(19) United States
(12) Patent Application Publication
(10) Pub. No.: US 2024/0393698 A1
(43) Pub. Date: Nov. 28, 2024

(54) COMPOSITION FOR REMOVING EDGE BEADS FROM METAL-CONTAINING RESISTS, DEVELOPER COMPOSITION OF METAL-CONTAINING RESISTS, AND METHOD OF FORMING PATTERNS USING THE COMPOSITION

(71) Applicant: SAMSUNG SDI CO., LTD., Yongin-si (KR)

(72) Inventors: Si-Kyun PARK, Suwon-si (KR); Minsoo KIM, Suwon-si (KR); Jin-Hee BAE, Suwon-si (KR); Hyungrang MOON, Suwon-si (KR); Taeksoo KWAK, Suwon-si (KR); Jongpil HO, Suwon-si (KR); Dong Wan RYU, Suwon-si (KR); Ahra CHO, Suwon-si (KR); Myoungsoo SONG, Suwon-si (KR); Gyeonghun PARK, Suwon-si (KR); Jin Hee CHOI, Suwon-si (KR)

(21) Appl. No.: 18/627,133

(22) Filed: Apr. 4, 2024

(30) Foreign Application Priority Data
May 23, 2023 (KR) 10-2023-0066536

(51) Int. Cl. G03F 7/32; G03F 7/004; G03F 7/16

(52) U.S. Cl. CPC G03F 7/325; G03F 7/0042; G03F 7/168

(57) ABSTRACT

A composition configured for removing edge beads from metal-containing resists and/or as a developer composition of metal-containing resists is water-free and includes an organic solvent and at least one additive selected from among an amino acid-based compound, a sulfur-containing acid compound, and a sulfur-containing amine-based compound. A method of forming patterns using the composition includes coating a metal-containing resist composition on a substrate; coating the composition configured for removing edge beads from metal-containing resists of the present embodiments along edges of the substrate; drying and heating to form a metal-containing resist film on the substrate; exposing the metal-containing photoresist film; and developing the metal-containing resist film with the developer composition of metal-containing resists.

### CROSS-REFERENCE TO RELATED APPLICATION

The present application claims priority to and the benefit of Korean Patent Application No. 10-2023-0066536, filed on May 23, 2023, in the Korean Intellectual Property Office, the entire content of which is incorporated herein by reference.

### BACKGROUND

### 1. Field

One or more aspects of embodiments of this disclosure are directed toward to a composition for removing edge beads from metal-containing resists and/or a developer composition of metal-containing resists, and a method of forming patterns utilizing the same.

### 2. Description of the Related Art

In recent years, the semiconductor industry has seen a substantially continuous reduction of critical dimensions (e.g., reduction in size), and this dimensional reduction requires or desires new types (or kinds) of high-performance photoresist materials and a patterning method that satisfy a demand or desire for processing and patterning with increasingly smaller features.

In addition, with the recent rapid development of the semiconductor industry, a semiconductor device is required or desired to have a suitably fast operation speed and a suitably large storage capacity, and in line with this requirement or desire, process technology for improving integration, reliability, and/or a response speed of the semiconductor device is being developed. For example, it is important to (relatively) accurately control/implant impurities in working regions of a silicon substrate and to interconnect these regions to form a device and an ultra-high-density integrated circuit, which may be achieved by a photolithographic process. For example, it is important to suitably integrate the photolithographic process including coating a photoresist on the substrate, selectively exposing it to ultraviolet (UV) (including extreme ultraviolet (EUV)), electron beams, X rays, and/or the like, and then, developing it.

For example, in the process of forming the photoresist film, the resist may be (substantially) coated on the substrate, (mainly) while rotating the silicon substrate, wherein the resist is coated on an edge and rear surface of the substrate, which may cause indentation and/or pattern defects in the subsequent semiconductor processes such as etching and/or ion implantation processes. Accordingly, a process of stripping and removing the photoresist coated on the edge and rear surface of the silicon substrate by utilizing a thinner composition, for example, an EBR (edge bead removal) process is performed. The EBR process requires (or may need) a composition that exhibits excellent or suitable solubility for the photoresist and effectively or suitably removes the beads and the photoresist remaining in the substrate and generates no (or substantially no) resist residue.

In addition, development of a photoresist and a developer composition capable of ensuring excellent or suitable etch resistance and resolution in the photolithographic process and concurrently (e.g., simultaneously), improving sensitivity and CD (critical dimension) uniformity and also, improving LER (line edge roughness) characteristics is required or desired in the industry.

### SUMMARY

One or more aspects of embodiments of the present disclosure provide a composition for removing edge beads from metal-containing resists and/or a developer composition of metal-containing resists.

One or more aspects of embodiments of the present disclosure provide a method of forming patterns utilizing the composition.

A composition for removing (or configured to remove) edge beads from metal-containing resists and/or as a developer composition of metal-containing resists according to some example embodiments is water-free and includes an organic solvent and at least one additive selected from among an amino acid-based compound, a sulfur-containing acid compound, and a sulfur-containing amine-based compound.

A moisture content (e.g., amount) of the composition for removing edge beads of metal-containing resists and/or as the developer composition of metal-containing resists may be less than or equal to about 1,000 ppm.

The amino acid-based compound may be represented by at least one of Chemical Formula 1 to Chemical Formula 3.

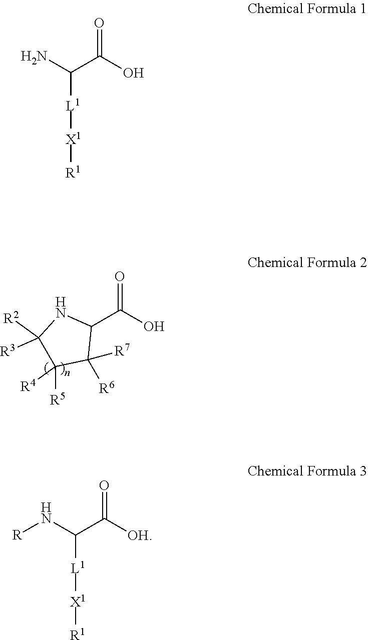

In Chemical Formulae 1 to 3,
L¹ may be a single bond, a substituted or unsubstituted C1 to C10 alkylene group, or a substituted or unsubstituted C6 to C20 arylene group,
X¹ may be a single bond, O, S, or a substituted or unsubstituted C1 to C10 alkylene group,
R may be a substituted or unsubstituted C1 to C10 alkyl group, or a substituted or unsubstituted C6 to C20 aryl group,
R¹ to R⁷ may each independently be hydrogen, a hydroxyl group, a mercapto group, an amino group, an amide group, a guanidino group, a carboxyl group, a substituted or unsubstituted C1 to C10 alkyl group, a substituted or unsubstituted C6 to C20 aryl group, or a substituted or unsubstituted C2 to C30 heteroaryl group, and
n may be an integer of 0 or 1.

The amino acid-based compound may be at least one of alanine, glycine, valine, leucine, isoleucine, proline, methionine, phenylalanine, tyrosine, tryptophan, serine, threonine, cysteine, asparagine, glutamine, aspartic acid, glutamic acid, histidine, lysine, arginine, or N-methylcysteine.

The sulfur-containing acid compound may be represented by Chemical Formula 4 or Chemical Formula 5.

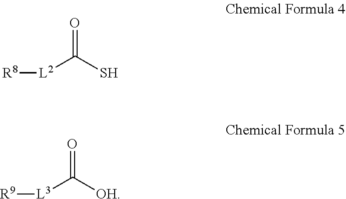

In Chemical Formulae 4 and 5,
L² and L³ may each independently be a single bond, a substituted or unsubstituted C1 to C10 alkylene group, or a substituted or unsubstituted C6 to C20 arylene group,
R⁸ may be a substituted or unsubstituted C1 to C10 alkyl group, a substituted or unsubstituted C6 to C20 aryl group, or a substituted or unsubstituted C2 to C30 heteroaryl group, and
R⁹ may be a sulfur-containing substituted or unsubstituted C1 to C10 alkyl group, a sulfur-containing substituted or unsubstituted C3 to C10 heterocycloalkyl group, a sulfur-containing substituted or unsubstituted C6 to C30 aryl group, or a sulfur-containing substituted or unsubstituted C2 to C30 heteroaryl group.

The sulfur-containing acid compound may be selected from compounds listed in Group 1:

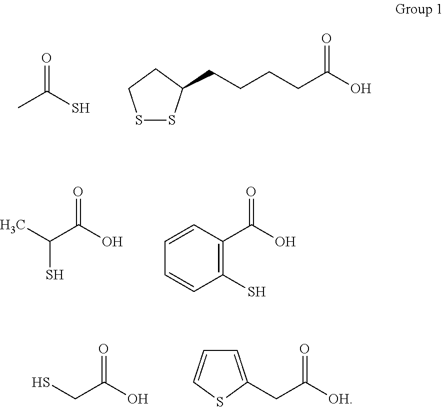

The sulfur-containing amine-based compound may be represented by Chemical Formula 6.

NH₂-L⁴-R¹⁰. Chemical Formula 6

In Chemical Formula 6,
L⁴ may be a single bond, a substituted or unsubstituted C1 to C10 alkylene group, or a substituted or unsubstituted C6 to C20 arylene group, and
R¹⁰ may be a sulfonamide group, a sulfonic acid salt, a sulfone group, a sulfoxide group, a thiol group, a thiolate group, a thioester group, a thioether group, a thioamide group, a sulfur-containing substituted or unsubstituted C3 to C10 heterocycloalkyl group, or a sulfur-containing substituted or unsubstituted C2 to C30 heteroaryl group.

The sulfur-containing amine-based compound may be selected from compounds listed in Group 2:

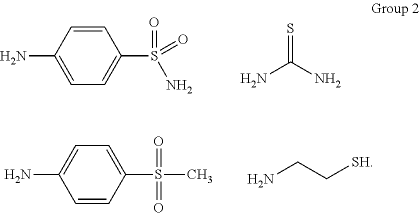

The composition for removing edge beads from the metal-containing resists and/or as the developer composition of the metal-containing resists may include about 50 to about 99.99 wt % of the organic solvent; and about 0.01 to about 50 wt % of the additive.

A metal compound included in the metal-containing resists may include at least one of an organic oxy group-containing tin compound or an organic carbonyloxy group-containing tin compound.

A metal compound included in the metal-containing resists may be represented by Chemical Formula 7.

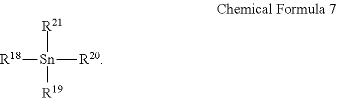

In Chemical Formula 7,
R¹⁸ to R²¹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} (wherein L^{a} is a single bond, or a substituted or unsubstituted C1 to C20 alkylene group and R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) or OC(═O) R^{c} (wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one of R¹⁹ to R²¹ may each independently be selected from among L^{a}-O—R^{a} and OC(═O) R^{c},
R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

A method of forming patterns according to some embodiments includes coating a metal-containing resist composition on a substrate; coating the composition for removing (or configured to remove) edge beads from the metal-containing resists of the present embodiments along the edges of the substrate; drying and heating to form a metal-containing resist film on the substrate; exposing the metal-containing photoresist film; and developing the metal-containing photoresist film.

A method of forming patterns according to some embodiments includes coating a metal-containing resist composition on a substrate; removing edge beads of the metal-containing resist, drying and heating to form a metal-containing resist film on the substrate; exposing the metal-containing photoresist film; and developing the metal-containing photoresist film utilizing the developer composition of the metal-containing resists of the present embodiments.

A method of forming patterns according to some embodiments includes coating the composition for removing (or configured to remove) edge beads from the metal-containing resists along the edges of a substrate; drying and heating to form a metal-containing resist film on the substrate; exposing the metal-containing photoresist film; and developing the metal-containing photoresist film utilizing the developer composition of the metal-containing resists.

The composition for removing edge beads from metal-containing resists according to some embodiments may meet the demands or desire for processing and patterning materials with smaller features by removing the metal-containing resists coated on the edge and/or rear surface of the substrate and thus reducing metal-based contaminations.

The metal-containing developer composition (e.g., the developer composition of the metal-containing resists) according to some embodiments minimizes or reduces defects in a metal-containing photoresist film after an exposure process and facilitates development, thereby providing excellent or suitable contrast characteristics, excellent or suitable sensitivity, and implementing reduced line edge roughness (LER).

### BRIEF DESCRIPTION OF THE DRAWINGS

FIG. 1 is a schematic view showing the photoresist coating apparatus according to the present embodiments.

FIGS. 2-4 are cross-sectional views illustrating a process sequence of the method of forming patterns according to the present embodiments.

### DETAILED DESCRIPTION

Hereinafter, referring to the drawings, embodiments of the present disclosure are described in more detail. In the following description of the present disclosure, the functions and/or constructions that should be understood by those of ordinary skill in the art will not be described for reasons of clarity and brevity.

In an effort to clearly and succinctly illustrate the present disclosure, some description and relationships may be omitted, and throughout the disclosure, the same or similar configuration elements are designated by the same reference numerals. Also, because the size and thickness of each configuration shown in the drawing are arbitrarily shown for better understanding and ease of description, the present disclosure is not necessarily limited thereto.

In the drawings, the thickness of layers, films, panels, regions, etc., are exaggerated for clarity. In the drawings, the thickness of a part of layers or regions, etc., is exaggerated for clarity. It will be understood that when an element such as a layer, film, region, or substrate is referred to as being “on” another element, it can be directly on the other element (e.g., without any intervening element therebetween) or one or more intervening elements may also be present.

In the present disclosure, “substituted” refers to a group or substituents in which a hydrogen atom is replaced by deuterium, a halogen group, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” refers to a group or substituent in which a hydrogen atom remains as a hydrogen atom without being replaced by another substituent.

In the present disclosure, the term “alkyl group” refers to a linear or branched aliphatic hydrocarbon group, unless otherwise defined. The alkyl group may be a “saturated alkyl group” that does not contain any double or triple bonds.

The alkyl group may be a C1 to C20 alkyl group. For example, the alkyl group may be a C1 to C10 alkyl group or a C1 to C6 alkyl group. For example, a C1 to C5 alkyl group refers to that the alkyl chain contains 1 to 5 carbon atoms, and may be selected from among methyl, ethyl, propyl, iso-propyl, n-butyl, iso-butyl, sec-butyl, and t-butyl.

Non-limiting examples of the alkyl group may include a methyl group, an ethyl group, a propyl group, an isopropyl group, a butyl group, an isobutyl group, a t-butyl group, a pentyl group, a hexyl group, and/or the like.

In the present disclosure, when a definition is not otherwise provided, the term “cycloalkyl group” refers to a monovalent cyclic aliphatic hydrocarbon group.

The cycloalkyl group may refer to a cyclopropyl group, a cyclobutyl group, a cyclopentyl group, a cyclohexyl group, etc.

In the present disclosure, when a definition is not otherwise provided, the term “heterocycloalkyl group” refers to a monovalent cyclic aliphatic group containing at least one heteroatom selected from among N, O, S, P, and Si as a ring-forming atom.

In the present disclosure, when a definition is not otherwise provided, the term “alkenyl group” refers to a linear or branched aliphatic hydrocarbon group containing one or more carbon-carbon double bonds, and may be, for example, an aliphatic unsaturated alkenyl group containing one or more double bonds.

In the present disclosure, when a definition is not otherwise provided, the term “alkynyl group” refers to a linear or branched aliphatic hydrocarbon group containing one or more carbon-carbon triple bonds, and may be, for example, an unsaturated alkynyl group containing one or more triple bonds.

In the present disclosure, “aryl group” refers to a substituent in which all ring-forming atoms of a cyclic substituent have p-orbitals, and these p-orbitals form a conjugate structure (e.g., the group is aromatic), and the aryl group may include a monocyclic functional group or a fused ring polycyclic functional group (e.g., rings that share adjacent pairs of carbon atoms).

In the present description, “heteroaryl group” refers to a cyclic aromatic group containing at least one heteroatom selected from among N, O, S, P, and Si as a ring-forming atom. Two or more heteroaryl groups may be directly linked through a sigma bond, or when the heteroaryl group includes two or more rings, the two or more rings may be fused to each other. When the heteroaryl group is a fused ring, each cyclic ring may include 1 to 3 heteroatoms.

In some embodiments, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted benzophenanthrenyl group, a substituted or unsubstituted triphenylene group, a substituted or unsubstituted perylenyl group, a substituted or unsubstituted fluorenyl group, a substituted or unsubstituted indenyl group, or a combination thereof, but is not limited thereto.

For example, the substituted or unsubstituted C2 to C30 heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted carbazolyl group, a substituted or unsubstituted dibenzofuranyl group, or a substituted or unsubstituted dibenzothiophenyl group, a substituted or unsubstituted benzonaphtofuranyl group, a substituted or unsubstituted benzonaphthothiophenyl group, a substituted or unsubstituted benzofuranofluorenyl group, a substituted or unsubstituted benzothiophenefluorenyl group, or a combination thereof, but is not limited thereto.

It will be understood that, although the terms first, second, etc. may be used herein to describe various elements, these elements should not be limited by these terms. These terms are only used to distinguish one element from another element. Thus, a first element could be termed a second element without departing from the teachings of the present invention. Similarly, a second element could be termed a first element.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

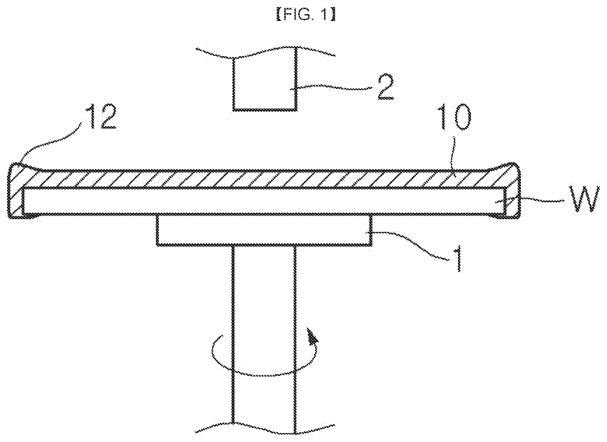

FIG. 1 is a schematic view showing the photoresist coating apparatus according to one or more of the present embodiments.

Referring to FIG. 1, a substrate support portion 1 on which a substrate W is placed is equipped therewith, and the substrate support portion 1 includes a spin chuck and/or a spin coater.

The substrate support portion 1 rotates in a first direction at a set or predetermined rotation speed to provide a centrifugal force to the substrate W. A spray nozzle 2 may be positioned on the substrate support portion 1 but located off (e.g., above) the upper portion of the substrate W in the atmospheric region so that the spray nozzle may be moved toward the upper portion of the substrate W and spray a photoresist solution 10 in the spraying step (or act). Accordingly, the photoresist solution 10 is coated on the surface of the substrate W by the centrifugal force. Herein, the photoresist solution 10 supplied to the center of the substrate W is coated while spreading to the edge of the substrate W by the centrifugal force, wherein a portion of photoresist solution 10 moves to the side surfaces of the substrate W and the lower surface of the edge of the substrate.

In some embodiments, in the coating process, the photoresist solution 10 is coated mainly in (e.g., by) a spin coating method, wherein a set or predetermined amount of the photoresist solution 10 with viscosity is supplied to the center portion of the substrate W and gradually spreads toward the edge of the substrate W by the centrifugal force.

Accordingly, the photoresist film may be evenly (or substantially evenly) formed by a rotational speed of the substrate support portion.

However, this rotation evaporates a solvent from the solution (e.g., the photoresist solution 10) and thereby gradually increases the (e.g., its) viscosity, thus resulting in a relatively large amount of the photoresist accumulated on the edge of the substrate by, for example, the action of surface tension, and further accumulated (e.g., severely) even on the lower surface of the edge of the substrate, which is referred to as edge beads 12.

Hereinafter, a composition for removing edge beads from metal-containing resists and/or a developer composition of metal-containing resists according to some embodiments is described.

A composition for removing edge beads from metal-containing resists and/or developer composition of metal-containing resists according to some embodiments of the present disclosure is water-free and includes an organic solvent and at least one additive selected from among an amino acid-based compound, a sulfur-containing acid compound, and a sulfur-containing amine-based compound.

Because the amino acid-based compound concurrently (e.g., simultaneously) includes an amine group and an acetate group, which improve a bonding force with a resist, the metal-containing resists may be effectively or suitably removed by applying a composition including the amino acid-based compound.

Because the sulfur-containing acid compound and the sulfur-containing amine-based compound contain sulfur, which improves the bonding force with the resist, the metal-containing resists also may be effectively or suitably removed by applying a composition including the sulfur-containing acid compound and/or the sulfur-containing amine-based compound.

In some embodiments, in the composition for removing edge beads from the metal-containing resists and/or the developer composition of the metal-containing resists, “water-free” refers to water not being selected or utilized as a component in the composition, but moisture of less than or equal to about 1,000 ppm may be included due to other impurities and/or external factors.

When the moisture content (e.g., amount) in the composition exceeds about 1,000 ppm, film quality deformation may occur due to hydration in the photoresist contact portion.

For example, the amino acid-based compound may be represented by at least one of Chemical Formula 1 to Chemical Formula 3.

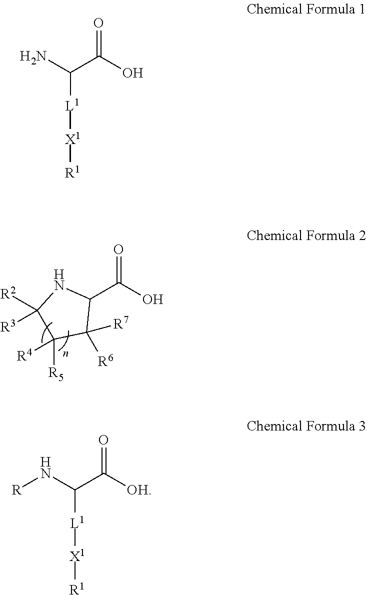

In Chemical Formulae 1 to 3,
L¹ may be a single bond, a substituted or unsubstituted C1 to C10 alkylene group, or a substituted or unsubstituted C6 to C20 arylene group,
X¹ may be a single bond, O, S, or a substituted or unsubstituted C1 to C10 alkylene group,
R may be a substituted or unsubstituted C1 to C10 alkyl group, or a substituted or unsubstituted C6 to C20 aryl group,
R¹ to R⁷ may each independently be hydrogen, a hydroxyl group, a mercapto group, an amino group, an amide group, a guanidino group, a carboxyl group, a substituted or unsubstituted C1 to C10 alkyl group, a substituted or unsubstituted C6 to C20 aryl group, or a substituted or unsubstituted C2 to C30 heteroaryl group, and
n is an integer of 0 or 1.

For example, R¹ may be hydrogen, a hydroxy group, a mercapto group, an amino group, an amide group, a guanidino group, a carboxyl group, a substituted or unsubstituted methyl group, a substituted or unsubstituted ethyl group, a substituted or unsubstituted isopropyl group, a substituted or unsubstituted isobutyl group, a substituted or unsubstituted sec-butyl group, a substituted or unsubstituted phenyl group, a substituted or unsubstituted indolyl group, or a substituted or unsubstituted imidazole group.

For example, R² to R⁷ may each independently be hydrogen, a substituted or unsubstituted methyl group, a substituted or unsubstituted ethyl group, a substituted or unsubstituted isopropyl group, a substituted or unsubstituted isobutyl group, or a substituted or unsubstituted sec-butyl group.

In this specification, the amino acid-based compound includes not only amino acid compounds but also compounds derived from amino acid compounds.

For example, the amino acid-based compound may be at least one of alanine, glycine, valine, leucine, isoleucine, proline, methionine, phenylalanine, tyrosine, tryptophan, serine, threonine, cysteine, asparagine, glutamine, aspartic acid, glutamic acid, histidine, lysine, arginine, or N-methylcysteine.

The sulfur-containing acid compound may be represented by Chemical Formula 4 or Chemical Formula 5.

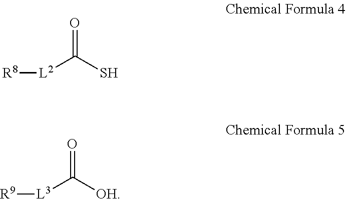

In Chemical Formulae 4 and 5,
L² and L³ may each independently be a single bond, a substituted or unsubstituted C1 to C10 alkylene group, or a substituted or unsubstituted C6 to C20 arylene group,
R⁸ may be a substituted or unsubstituted C1 to C10 alkyl group, a substituted or unsubstituted C6 to C20 aryl group, or a substituted or unsubstituted C2 to C30 heteroaryl group, and
R⁹ may be a sulfur-containing substituted or unsubstituted C1 to C10 alkyl group, a sulfur-containing substituted or unsubstituted C3 to C10 heterocycloalkyl group, a sulfur-containing substituted or unsubstituted C6 to C30 aryl group, or a sulfur-containing substituted or unsubstituted C2 to C30 heteroaryl group.

As utilized herein, “sulfur-containing” may include both a form substituted with a sulfur-containing group and a form containing sulfur in a heterocyclic ring as a ring-forming atom.

For example, R⁸ may be hydrogen, a substituted or unsubstituted methyl group, a substituted or unsubstituted ethyl group, a substituted or unsubstituted isopropyl group, a substituted or unsubstituted isobutyl group, or a substituted or unsubstituted sec-butyl group.

For example, R⁹ may be a substituted or unsubstituted 1,3-dithiolane, a substituted or unsubstituted thiophene, a thiol group, a substituted or unsubstituted C1 to C10 alkylthiol, or a substituted or unsubstituted C6 to C12 arylthiol group.

For example, the sulfur-containing acid compound may be selected from compounds listed in Group 1:

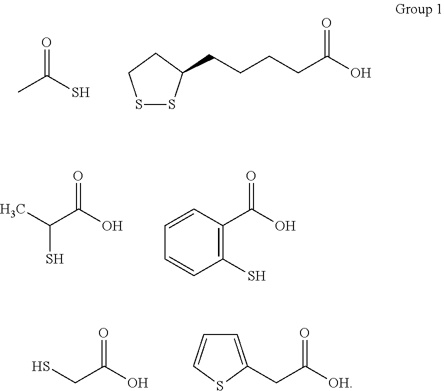

The sulfur-containing amine compound may be represented by Chemical Formula 6.

NH₂-L⁴-R¹⁰. Chemical Formula 6

In Chemical Formula 6,
L⁴ may be a single bond, a substituted or unsubstituted C1 to C10 alkylene group, or a substituted or unsubstituted C6 to C20 arylene group, and
R¹⁰ may be a sulfonamide group, a sulfonic acid salt, a sulfone group, a sulfoxide group, a thiol group, a thiolate group, a thioester group, a thioether group, a thioamide group, a sulfur-containing substituted or unsubstituted C3 to C10 heterocycloalkyl group, or a sulfur-containing substituted or unsubstituted C2 to C30 heteroaryl group.

For example, the sulfur-containing amine-based compound may be selected from compounds listed in Group 2:

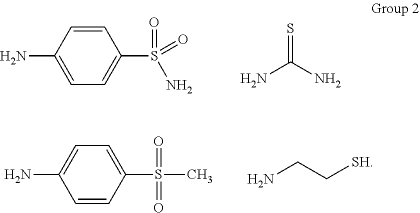

In one or more embodiments, the composition for removing edge beads from the metal-containing resists and/or the developer composition of the metal-containing resists is water-free, and includes about 0.01 to about 50 wt % of the additive of the present embodiments and about 50 to about 99.99 wt % of the organic solvent.

In some embodiments, the composition for removing edge beads from the metal-containing resists and/or the developer composition of the metal-containing resists may include the additive in an amount of about 0.05 to about 40 wt %, for example, about 0.5 to about 30 wt %, or about 1 to about 20 wt %.

The organic solvent included in the composition for removing edge beads from metal-containing resists and/or the developer composition according to some embodiments may be, for example, propylene glycol methyl ether (PGME), propylene glycol methyl ether acetate (PGMEA), propylene glycol butyl ether (PGBE), ethylene glycol methyl ether, diethylglycolethylmethylether, dipropylglycoldimethylether, ethanol, 2-butoxyethanol, n-propanol, isopropanol, n-butanol, isobutanol, hexanol, ethylene glycol, propylene glycol, heptanone, propylene carbonate, butylene carbonate, diethyl ether, dibutyl ether, ethyl acetate, methyl 3-methoxypropionate, ethyl 3-ethoxypropionate, diisopentyl ether, xylene, acetone, methylethylketone, methylisobutylketone, tetrahydrofuran, dimethylsulfoxide, dimethyl formamide, acetonitrile, diacetone alcohol, 3,3-dimethyl-2-butanone, N-methyl-2-pyrrolidone, dimethyl acetamide, cyclohexanone methyl-2-hydroxy-2-methylpropanoate (HBM), gamma butyrolactone (GBL), 1-butanol (n-butanol), ethyl lactate (EL), diene butylether (DBE), diisopropyl ether (DIAE), acetylacetone, n-butylactate, 4-methyl-2-pentenol (or referred to as methyl isobutyl carbinol (MIBC)), 1-methoxy-2-propanol, 1-ethoxy-2-propanol, toluene, xylene, methylethylketone, cyclopentanone, cyclohexanone, 2-hydroxyethyl propionate, 2-hydroxy-2-methylethyl propionate, ethoxyethyl acetate, hydroxyethyl acetate, 2-hydroxy-3-methylmethyl butanoate, 3-methoxymethyl propionate, 3-methoxyethyl propionate, 3-ethoxyethyl propionate, 3-ethoxymethyl propionate, methyl pyruvate, ethyl pyruvate, ethyl acetate, butyl acetate, ethyl lactate, butyl lactate, methyl-2-hydroxyisobutyrate, methoxy benzene, n-butyl acetate, 1-methoxy-2-propyl acetate, methoxyethoxy propionate, ethoxyethoxy propionate, or a mixture thereof, but is not limited thereto.

The composition for removing edge beads from metal-containing resists according to the present disclosure may be particularly effective or suitable in removing metal-containing resists, for example, undesirable metal residues such as tin-based metal residues.

In some embodiments, the developer composition of the metal-containing resists according to the present disclosure minimizes or reduces defects in the metal-containing photoresist film after an exposure process and enables easy or suitable development, thereby realizing excellent or suitable pattern characteristics.

In some embodiments, excellent or suitable sensitivity and/or reduced line edge roughness (LER) can be realized.

In some embodiments, other additives (to be described herein below) may be included, and in this case, the organic solvent may be included in a balance amount excluding other components of the composition.

A least one selected from among a surfactant, a dispersant, a moisture absorbent, and a coupling agent may be further included.

The surfactant may serve to improve coating uniformity and improve wetting of the photoresist composition. In some embodiments, the surfactant may be a sulfuric acid ester salt, a sulfonic acid salt, a phosphoric acid ester, a soap, an amine salt, a quaternary ammonium salt, a polyethylene glycol, an alkylphenol ethylene oxide adduct, a polyhydric alcohol, a nitrogen-containing vinyl polymer, or a combination thereof, but is not limited thereto. For example, the surfactant may include an alkylbenzene sulfonate salt, an alkylpyridinium salt, polyethylene glycol, and/or a quaternary ammonium salt. When the composition for removing edge beads from metal-containing resists or the developer composition of metal-containing resists includes the surfactant, the surfactant may be included in an amount of about 0.001 wt % to about 3 wt % based on a total weight of the composition for removing edge beads from metal-containing resists or the developer composition of metal-containing resists.

The dispersant may serve to uniformly (or substantially uniformly) disperse each component constituting the composition for removing edge beads from metal-containing resists or the developer composition of metal-containing resists in the composition for removing edge beads from metal-containing resists or the developer composition of metal-containing resists. In some embodiments, the dispersant may be an epoxy resin, polyvinyl alcohol, polyvinyl butyral, polyvinylpyrrolidone, glucose, sodium dodecyl sulfate, sodium citrate, oleic acid, linoleic acid, or a combination thereof, but is not limited thereto. When the composition for removing edge beads from metal-containing resists or the developer composition of metal-containing resists includes the dispersant, the dispersant may be included in an amount of about 0.001 wt % to about 5 wt % based on a total weight of the composition for removing edge beads from metal-containing resists or the developer composition of metal-containing resists.

The moisture absorbent may serve to prevent or reduce adverse effects by moisture in the composition for removing edge beads from metal-containing resists or the developer composition of metal-containing resists. For example, the moisture absorbent may serve to prevent or reduce the risk of the metal included in the composition for removing edge beads from metal-containing resists or the developer composition of metal-containing resists being oxidized by moisture. In some embodiments, the moisture absorbent may be polyoxyethylene nonylphenolether, polyethylene glycol, polypropylene glycol, polyacrylamide, or a combination thereof, but is not limited thereto. When the composition for removing edge beads from metal-containing resists or the developer composition of metal-containing resists includes the moisture absorbent, the moisture absorbent may be included in an amount of about 0.001 wt % to about 10 wt % based on a total weight of the composition for removing edge beads from metal-containing resists or the developer composition of metal-containing resists.

The coupling agent may serve to improve adhesion to the lower film. In some embodiments, the coupling agent may include a silane coupling agent. The silane coupling agent may be vinyltrimethoxysilane, vinyltriethoxysilane, vinyl trichlorosilane, vinyltris(β-methoxyethoxy) silane, 3-methacryloxypropyltrimethoxysilane, 3-acryloxypropyl trimethoxysilane, p-styryl trimethoxysilane, 3-methacryloxypropylmethyldimethoxysilane, 3-methacryloxypropylmethyldiethoxysilane, and/or trimethoxy [3-(phenylamino) propyl]silane, but is not limited thereto. When the composition for removing edge beads from metal-containing resists or the developer composition of metal-containing resists includes the coupling agent, the coupling agent may be included in an amount of about 0.001 wt % to about 5 wt % based on a total weight of the composition for removing edge beads from metal-containing resists or the developer composition of metal-containing resists.

The metal compound included in the metal-containing resists may include at least one of (e.g., any one of) an organic oxy group-containing tin compound or an organic carbonyloxy group-containing tin compound.

For example, the metal compound included in the metal-containing resists may be represented by Chemical Formula 7.

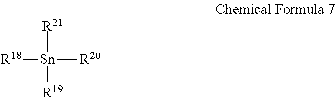

In Chemical Formula 7,
R¹⁸ to R²¹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} (wherein L^{a} is a single bond, or a substituted or unsubstituted C1 to C20 alkylene group and R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) or OC(═O) R^{c} (wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and,
at least one of R¹⁹ to R²¹ are each independently L^{a}-O—R^{a} or OC(═O) R^{c}.
R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

The metal compound included in the metal-containing resists may be at least one of (e.g., any one of) an organic oxy group-containing tin compound or an organic carbonyloxy group-containing tin compound.

For example, the metal compound included in the metal-containing resists may be at least one of an alkyloxy group-containing tin compound or an alkylcarbonyloxy group-containing tin compound.

According to some embodiments, a method of forming patterns includes the step (or act or process) of removing the edge beads utilizing the composition for removing edge beads from the metal-containing resist of the present embodiments. For example, the manufactured (formed) pattern may be a photoresist pattern. In some embodiments, it may be a negative-type or kind photoresist pattern.

A method of forming patterns according to some embodiments includes coating a metal-containing resist composition on a substrate; coating the composition for removing edge beads from the metal-containing resists of the present embodiments along the edges of the substrate; drying and heating the coating to form a metal-containing resist film on the substrate; exposing the metal-containing photoresist film; and developing the metal-containing photoresist film.

In some embodiments, the forming of patterns utilizing the metal-containing resist composition may include coating a metal-containing resist composition on a substrate to form a thin film by spin coating, slit coating, inkjet printing, etc., and drying the coated metal-containing resist composition to form a photoresist film. The metal-containing resist composition may include a tin-based compound, and for example, the tin-based compound may include at least one of an organic oxy group-containing tin compound or an organic carbonyloxy group-containing tin compound.

For example, the composition for removing edge beads from metal-containing resists of the present embodiments may be coated along the edge of the substrate in an appropriate or suitable amount while rotating the substrate at an appropriate or suitable speed (e.g., 500 rpm or more).

Subsequently, a first heat treatment process of heating the substrate on which the photoresist film is formed is performed. The first heat treatment process may be performed at a temperature of about 80° C. to about 120° C. and in this process, the solvent is evaporated and the photoresist film may be more firmly adhered to the substrate.

Then the photoresist film is selectively exposed.

For example, examples of light that may be utilized in the exposure process may include not only light having a short wavelength (such as i-line (wavelength 365 nm), KrF excimer laser (wavelength 248 nm), and/or ArF excimer laser (wavelength 193 nm)), but also light having a high energy wavelength (such as EUV (Extreme UltraViolet, wavelength 13.5 nm), E-Beam (electron beam), etc.)

In some embodiments, the light for exposure according to some embodiments may be short-wavelength light having a wavelength range of about 5 nm to about 150 nm, and may be light having a high energy wavelength such as EUV (Extreme UltraViolet, wavelength 13.5 nm), E-Beam (electron beam), etc.

In the step (or act) of forming the photoresist pattern, a negative-type or kind pattern may be formed.

The exposed region of the photoresist film has a solubility different from that of the unexposed region of the photoresist film as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist film becomes difficult to be dissolved in a developer (e.g., developing composition).

For example, the photoresist pattern corresponding to the negative tone image may be completed by dissolving and removing the photoresist film corresponding to the unexposed region utilizing an organic solvent such as 2-heptanone.

The developer utilized in the method of forming patterns according to the embodiments may be an organic solvent, for example, a ketone (such as methyl ethyl ketone, acetone, cyclohexanone, and/or 2-haptanone), an alcohol (such as 4-methyl-2-propanol, 1-butanol, isopropanol, 1-propanol, and/or methanol), an ester (such as propylene glycol monomethyl ether acetate, ethyl acetate, ethyl lactate, n-butyl acetate, and/or butyrolactone), an aromatic compound (such as benzene, xylene, and/or toluene), or a combination thereof.

According to some embodiments, the photoresist pattern formed by exposure to not only light having a wavelength such as i-line (wavelength 365 nm), KrF excimer laser (wavelength 248 nm), and/or ArF excimer laser (wavelength 193 nm), but also EUV (Extreme UltraViolet; wavelength 13.5 nm), as well as light having high energy such as an E-beam (electron beam), may have a thickness width (e.g., thickness) of about 5 nm to about 100 nm. For example, the photoresist pattern may be formed to have a thickness width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In some embodiments, the photoresist pattern may have a pitch having a half-pitch of less than or equal to about 50 nm, for example less than or equal to about 40 nm, for example less than or equal to about 30 nm, for example less than or equal to about 20 nm, for example less than or equal to about 15 nm, and may have a line width roughness of less than or equal to about 10 nm, less than or equal to about 5 nm, less than or equal to about 3 nm, or less than or equal to about 2 nm.

A method of forming patterns according to some embodiments includes coating a metal-containing resist composition on a substrate, removing edge beads of the metal-containing resist, drying and heating to form a metal-containing resist film on the substrate, exposing the metal-containing photoresist film, and developing the metal-containing photoresist film utilizing the developer composition of the metal-containing resists.

The coating of the metal-containing resist composition on a substrate is the same as described above.

The removing of edge beads of the metal-containing resists may be performed by coating an appropriate or suitable amount of a suitable organic solvent and/or composition for removing edge beads along the edge of the substrate while spinning the substrate at an appropriate or suitable speed (e.g., 500 rpm or more).

The drying and heating to form a metal-containing resist film on the substrate is the same as described above.

The exposing of the metal-containing photoresist film is the same as described above.

The photoresist pattern corresponding to the negative tone image may be completed by dissolving the unexposed regions of the photoresist film by utilizing the developer composition of metal-containing resists of the present embodiments, and then removing the photoresist film.

Hereinafter, a method of forming patterns by development is described in more detail with reference to the drawings.

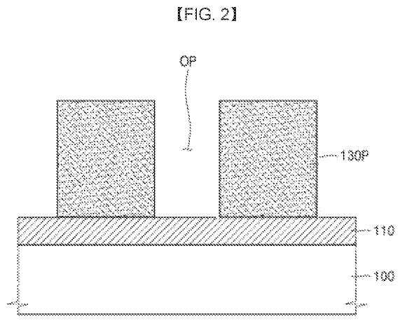

FIGS. 2 to 4 are cross-sectional views illustrating a process sequence to help explain a method of forming patterns.

Referring to FIG. 2, the exposed photoresist film is developed to form a photoresist pattern 130P.

In some embodiments, the exposed photoresist film may be developed to remove an unexposed region of the photoresist film, and the photoresist pattern 130P including the exposed region of the photoresist film may be formed. The photoresist pattern 130P may include a plurality of openings OP.

In one or more embodiments, the development of the photoresist film may be performed through an NTD (negative-tone development) process. Herein, the metal-containing photoresist developer composition according to some embodiments may be utilized as a developer composition.

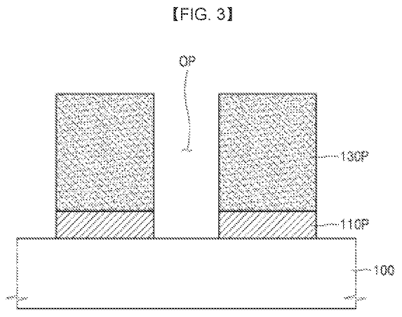

Referring to FIG. 3, the photoresist pattern 130P is utilized to process a feature layer 110 illustrated in FIG. 2.

The feature layer 110 may be processed through one or more suitable processes of etching a feature layer 110 exposed through the openings OP of the photoresist pattern 130P, for example, injecting impurity ions into the feature layer 110, forming an additional film on the feature layer 110 through the openings OP, deforming a portion of the feature layer 110 through the openings OP, and/or the like. FIG. 3 illustrates an example process of forming a feature pattern 110P by etching the feature layer 110 exposed through the openings OP.

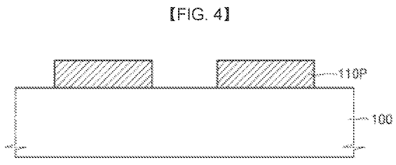

Referring to FIG. 4, the photoresist pattern 130P remaining on the feature pattern 110P in the result of FIG. 3 is removed. In order to remove the photoresist pattern 130P, an ashing and/or stripping process may be utilized.

A method of forming patterns according to some embodiments includes coating a metal-containing resist composition on a substrate, coating the composition for removing edge beads from the metal-containing resists of the present embodiments along the edges of the substrate, drying and heating to form a metal-containing resist film on the substrate, exposing the metal-containing photoresist film, and developing the metal-containing photoresist film utilizing the developer composition of the metal-containing resists of the present embodiments.

Each step (or act) of the method may be the same as described above, but in the removing step (or act or process) of edge beads and the developing step (or act or process), the composition for removing edge beads from metal-containing resists and/or the developer composition of metal-containing resists according to the present disclosure may be concurrently (e.g., simultaneously) utilized to effectively or suitably improve an effect of removing the edge beads and improve solubility of the unexposed region, thus satisfying needs or desires for processing and patterning of smaller features, resultantly realizing excellent or suitable contrast characteristics, excellent or suitable sensitivity, and reduced line edge roughness (LER).

Hereinafter, the present disclosure will be described in more detail through examples relating to the preparation of the composition for removing edge beads from metal-containing resists and the developer composition of metal-containing resists of the present embodiments. However, the technical features of the present disclosure are not limited by the following examples.

### Preparation of Composition for Removing Edge Beads from Metal-Containing Resists/Developer Composition

### Example 1

A cysteine compound was mixed with a solvent of propylene glycol methyl ether acetate (PGMEA) and ethyllactate (EL) mixed in a weight ratio of 9:1 to prepare a composition as shown in Table 1 and completely dissolved therein by shaking at room temperature (25° C.). Subsequently, the solution was passed through a PTFE filter with a pore size of 1 μm, thus obtaining a final composition.

### Examples 2 to 4 and Comparative Examples 1 to 3

Each composition was obtained in substantially the same manner as in Example 1 except that the composition was varied as shown in Table 1.

TABLE 1

| | Compositions for removing edge beads from metal- | |
|---|---|---|
| | containing resists/developer composition | |
| | Additive (wt %) | Solvent (wt %) |
| Example 1 | cysteine (1) | PGMEA/EL (99) |
| Example 2 | N-methyl cysteine (1) | PGMEA/EL (99) |
| Example 3 | glycine (1) | PGMEA/EL (99) |
| Example 4 | thioacetic acid (1) | PGMEA/EL (99) |
| Comparative | dimethylamine (40) | PGMEA/EL (60) |
| Example 1 | | |
| Comparative | acetic acid (40) | PGMEA/EL (60) |
| Example 2 | | |
| Comparative | glycine (1) | PGMEA/EL (94)/H₂O (5) |
| Example 3 | | |

### Preparation Example: Preparation of Organometal-Containing Photoresist Composition

A photoresist composition was prepared by dissolving an organometallic compound with a structure of Chemical Formula C in 4-methyl-2-pentanol at a concentration of 1 wt % and filtering the solution with a 0.1 μm PTFE syringe filter.

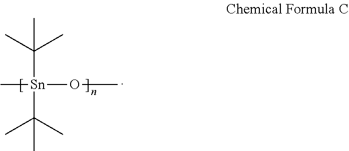

### Evaluation 1: Evaluation of Residual Film Thickness (Strip Test) and Sn Residual Amount Before Development

Onto a 6-inch silicon wafer, 1.0 mL of the organometallic compound-containing photoresist composition according to the Preparation Example was put and then, allowed to stand for 20 seconds and spin-coated at 800 rpm for 30 seconds. Subsequently, a coating film obtained through a heat treatment at 180° C. for 60 seconds was measured with respect to a thickness in an ellipsometry method. Onto the wafer on which the coating film was formed, 10 mL of each of the compositions for removing edge beads according to Examples 1 to 4 and Comparative Examples 1 to 3, respectively, was placed along an edge thereof and spin-coated for 5 seconds and then, dried, while rotating at 1,500 rpm. Subsequently, a film obtained through a heat treatment at 150° C. for 60 seconds was remeasured with respect to a thickness in the ellipsometry method, and then, a thickness change before and after the edge bead removal process (e.g., before and after the coating of the composition for removing edge beads) was calculated and evaluated according to the following criteria, and in addition, a residual amount of Sn was measured through a VPD ICP-MS analysis, and the results are shown in Table 2.
residual thickness was less than 2 Å: ∘
residual thickness was greater than or equal to 2 Å: X

TABLE 2

| | | Residual Sn Amount |
|---|---|---|
| | Strip test | (×10¹⁰ atoms/cm²) |
| Example 1 | ◯ | 11000 |
| Example 2 | ◯ | 11000 |
| Example 3 | ◯ | 12000 |
| Example 4 | ◯ | 10000 |
| Comparative Example 1 | X | 56000 |
| Comparative Example 2 | ◯ | 33000 |
| Comparative Example 3 | X | 28000 |

Referring to Table 2, the compositions for removing edge beads of metal-containing resists according to the Examples exhibited excellent or suitable metal removal effects and thus further promoted a decrease of residual metals, compared with the compositions for removing edge beads of metal-containing resists according to the Comparative Examples, and in addition, even if the same compound (e.g., additive) and organic solvent were utilized, but water was further included (e.g., added as a component in the composition, i.e., not water-free), as in Comparative Example 3, the metal removal effect was relatively deteriorated.

### Evaluation 2: Contrast Performance

The metal-containing photoresist (PR) compositions prepared above were spin-coated on an 8-inch wafer at 1,500 rpm for 30 seconds, and then heat treated at 130° C. for 60 seconds to manufacture a coated wafer.

After exposing the coated wafer at a dose of 10 mJ to 100 mJ in a rectangular pattern with a size of 1.2 cm×0.9 cm by utilizing a KrF scanner (PAS 5500/700D, ASML) and heat-treating it at 170° C. for 60 seconds, the developer compositions according to Examples 1 to 4 and Comparative Examples 1 to 3 were respectively applied thereto for developing and then, heat-treated at 180° C. for 60 seconds, to complete a patterned wafer. The patterned wafer was measured with respect to a thickness of each exposure area to obtain a contrast curve, which was utilized to calculate contrast (Y) performance and sensitivity (Do), and the results are shown in Table 1.

$$γ ( contrast ) = 1 / log ( {D}_{100} / {D}_{0} )$$

D₁₀₀=exposure dose at which 100% of PR remains
D₀=exposure dose at which PR is completely removed

### Evaluation 3: Evaluation of Sensitivity and Line Edge Roughness (LER)

A linear array of 50 circular pads with a diameter of 500 μm was projected onto a wafer by utilizing EUV light (Lawrence Berkeley National Laboratory Micro Exposure Tool, MET). Herein, exposure time of the pads was adjusted, so that an incremental EUV dose was applied to each pad.

Subsequently, a resist and a substrate therefrom were exposed at 160° C. for 120 seconds on a hot plate and then, post-exposure baked (PEB). The baked film was dipped respectively in each of the developers of Examples 1 to 4 and Comparative Examples 1 to 3 for 30 seconds and then, additionally washed with the same developer for 15 seconds, forming a negative tone image, that is, removing the unexposed coating portion. The process was terminated by baking the film at 150° C. for 2 minutes on the hot plate.

The exposed pads were measured with respect to a residual resist thickness by utilizing an ellipsometer. The residual resist thickness for each exposure dose was measured and graphed as a function of the exposure dose and then, Dg (an energy level at which development was completed) was evaluated in two categories according to the following criteria, and the results are shown in Table 3.

In some embodiments, an FE-SEM image was utilized to confirm a line, of which line edge roughness (LER) was measured and then, evaluated in three categories according to the following criteria, and the results are shown in Table 3.

### Sensitivity

A: less than 16 mJ/cm2
B: greater than or equal to 16 mJ/cm2

### Line Edge Roughness (LER)

∘: less than or equal to 4 nm
Δ: greater than 4 nm and less than or equal to 7 nm
X: greater than 7 nm

TABLE 3

| | γ (contrast) | Sensitivity (D₀) | LER |
|---|---|---|---|
| Example 1 | 35.2 | A | ◯ |
| Example 2 | 36.9 | A | ◯ |
| Example 3 | 34.2 | A | ◯ |
| Example 4 | 35.3 | A | ◯ |
| Comparative Example 1 | 15.2 | B | X |
| Comparative Example 2 | 14.2 | B | Δ |
| Comparative Example 3 | 14.5 | B | Δ |

* HP: half pitch reference

Referring to Table 3, when the developer compositions for metal-containing photoresists of the Examples were applied, compared with when the developer compositions for metal-containing photoresists of the Comparative Examples, excellent or suitable contrast performance, excellent or suitable sensitivity, and reduced line edge roughness were achieved.

A pattern forming system or device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinbefore, certain embodiments of the present disclosure have been described and illustrated, however, it should be apparent to a person with ordinary skill in the art that the present disclosure is not limited to the embodiments as described herein, and may be variously suitably modified and transformed without departing from the spirit and scope of the present disclosure. Accordingly, the modified and/or transformed embodiments as such should not be understood separately from the technical ideas and aspects of the present disclosure, and the modified embodiments are within the scope of the claims of the present disclosure and their equivalents.

Description of Symbols

| | |
|---|---|
| 1: substrate support portion | 2: spray nozzle |
| 10: photoresist solution | 12: edge bead |
| 100: substrate | OP: opening |
| 110: feature layer | |
| 110P: feature pattern | 130P: photoresist pattern |

What is claimed is:

1. A composition,
the compositing being for removing edge beads from metal-containing resists and/or being a developer composition of metal-containing resists,
the composition being water-free,
the composition comprising an organic solvent and an additive, and
the additive being at least one of an amino acid-based compound, a sulfur containing acid compound, or a sulfur containing amine-based compound.

2. The composition as claimed in claim 1, wherein
a moisture content is less than or equal to about 1,000 ppm.

3. The composition as claimed in claim 1, wherein
the amino acid-based compound is represented by at least one of Chemical Formula 1 to Chemical Formula 2: 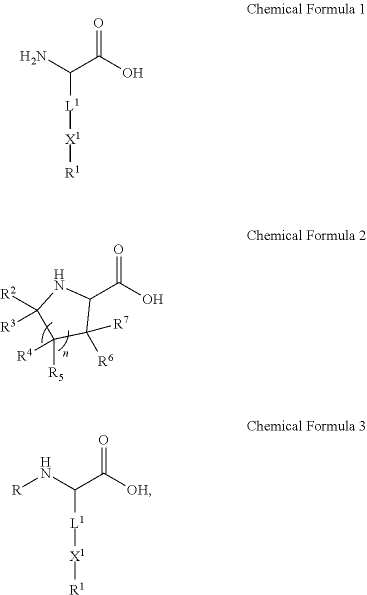
wherein, in Chemical Formulae 1 to 3,
L¹ is a single bond, a substituted or unsubstituted C1 to C10 alkylene group, or a substituted or unsubstituted C6 to C20 arylene group,
X¹ is a single bond, O, S, or a substituted or unsubstituted C1 to C10 alkylene group,
R is a substituted or unsubstituted C1 to C10 alkyl group, or a substituted or unsubstituted C6 to C20 aryl group,
R¹ to R⁷ are each independently hydrogen, a hydroxyl group, a mercapto group, an amino group, an amide group, a guanidino group, a carboxyl group, a substituted or unsubstituted C1 to C10 alkyl group, a substituted or unsubstituted C6 to C20 aryl group, or a substituted or unsubstituted C2 to C30 heteroaryl group, and
n is an integer of 0 or 1.

4. The composition as claimed in claim 1, wherein
the amino acid-based compound is at least one of alanine, glycine, valine, leucine, isoleucine, proline, methionine, phenylalanine, tyrosine, tryptophan, serine, threonine, cysteine, asparagine, glutamine, aspartic acid, glutamic acid, histidine, lysine, arginine, or N-methyl cysteine.

5. The composition as claimed in claim 1, wherein
the sulfur-containing acid compound is represented by Chemical Formula 4 or Chemical Formula 5: 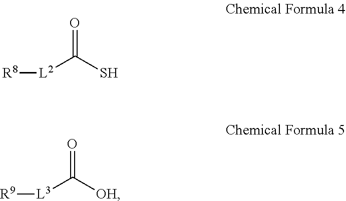
wherein, in Chemical Formulae 4 and 5,
L² and L³ are each independently a single bond, a substituted or unsubstituted C1 to C10 alkylene group, or a substituted or unsubstituted C6 to C20 arylene group,
R⁸ is a substituted or unsubstituted C1 to C10 alkyl group, a substituted or unsubstituted C6 to C20 aryl group, or a substituted or unsubstituted C2 to C30 heteroaryl group, and
R⁹ is a sulfur-containing substituted or unsubstituted C1 to C10 alkyl group, a sulfur-containing substituted or unsubstituted C3 to C10 heterocycloalkyl group, a sulfur-containing substituted or unsubstituted C6 to C30 aryl group, or a sulfur-containing substituted or unsubstituted C2 to C30 heteroaryl group.

6. The composition as claimed in claim 1, wherein
the sulfur-containing acid compound is one of compounds in Group 1: Group 1

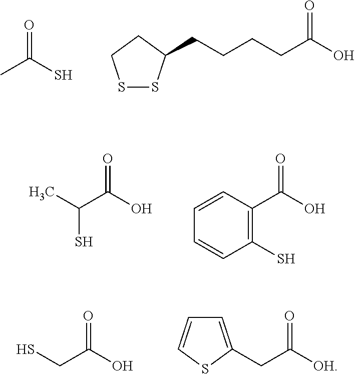

7. The composition as claimed in claim 1, wherein
the sulfur-containing amine-based compound is represented by Chemical Formula 6:
NH₂-L⁴-R¹⁰, and Chemical Formula 6
wherein, in Chemical Formula 6,
L⁴ is a single bond, a substituted or unsubstituted C1 to C10 alkylene group, or a substituted or unsubstituted C6 to C20 arylene group, and
R¹⁰ is a sulfonamide group, a sulfonic acid salt, a sulfone group, a sulfoxide group, a thiol group, a thiolate group, a thioester group, a thioether group, a thioamide group, a sulfur-containing substituted or unsubstituted C3 to C10 heterocycloalkyl group, or a sulfur-containing substituted or unsubstituted C2 to C30 heteroaryl group.

8. The composition as claimed in claim 1, wherein
the sulfur-containing amine-based compound is selected from compounds in Group 2:

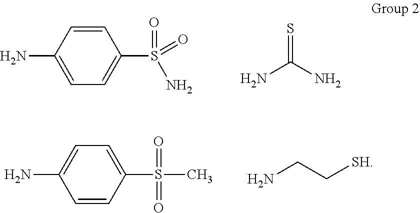

9. The composition as claimed in claim 1, comprising:
about 0.01 to about 50 wt % of the additive, and
about 50 to about 99.99 wt % of the organic solvent.

10. The composition as claimed in claim 1, wherein
a metal compound comprised in the metal-containing resists comprises at least one of an organic oxy group-containing tin compound or an organic carbonyloxy group-containing tin compound.

11. The composition as claimed in claim 1, wherein
a metal compound comprised in the metal-containing resists is represented by Chemical Formula 7: 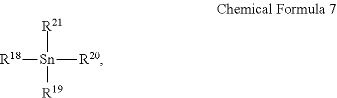
and
wherein, in Chemical Formula 7,
R¹⁸ to R²¹ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, L^{a}-O—R^{a} (wherein L^{a} is a single bond, or a substituted or unsubstituted C1 to C20 alkylene group and R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) or OC(═O)R^{c} (wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one of R¹⁹ to R²¹ are each independently L^{a}-O—R^{a} or OC(═O)R^{c}.

12. A method of forming patterns, the method comprising:
coating a metal-containing resist composition on a substrate;
coating the composition as claimed in claim 1 along edges of the substrate;
drying and heating to form a metal-containing resist film on the substrate;
exposing the metal-containing photoresist film; and
developing the metal-containing resist film.

13. A method of forming patterns, the method comprising:
coating a metal-containing resist composition on a substrate;
removing edge beads of the metal-containing resist composition;
drying and heating to form a metal-containing resist film on the substrate;
exposing the metal-containing resist film; and
developing the metal-containing resist film with the composition as claimed in claim 1.

14. A method of forming patterns, the method comprising:
coating a metal-containing resist composition on a substrate;
coating the composition as claimed in claim 1 along edges of the substrate;
drying and heating to form a metal-containing resist film on the substrate;
exposing the metal-containing photoresist film; and
developing the metal-containing resist film with the composition as claimed in claim 1.

15. A system of forming patterns, the system comprising:
means for coating a metal-containing resist composition on a substrate;
means for coating the composition as claimed in claim 1 along edges of the substrate;
means for drying and heating to form a metal-containing resist film on the substrate;
means for exposing the metal-containing photoresist film; and
means for developing the metal-containing resist film.

16. A system of forming patterns, the system comprising:
means for coating a metal-containing resist composition on a substrate;
means for removing edge beads of the metal-containing resist composition;
means for drying and heating to form a metal-containing resist film on the substrate;
means for exposing the metal-containing resist film; and
means for developing the metal-containing resist film with the composition as claimed in claim 1.

17. A system of forming patterns, the system comprising:
means for coating a metal-containing resist composition on a substrate;
means for coating the composition as claimed in claim 1 along edges of the substrate;
means for drying and heating to form a metal-containing resist film on the substrate;
means for exposing the metal-containing photoresist film; and
means for developing the metal-containing resist film with the composition as claimed in claim 1.
